(19) United States
(12) Patent Application Publication
(10) Pub. No.: US 2026/0032805 A1
(43) Pub. Date: Jan. 29, 2026

(54) ELECTRONIC SUBSTRATE UNIT AND BATTERY MONITORING SYSTEM

(71) Applicant: Hitachi Astemo, Ltd., Hitachinaka-shi, Ibaraki (JP)

(72) Inventors: Jun SUZUKI, Hitachinaka-shi (JP); Ei O, Hitachinaka-shi (JP)

(21) Appl. No.: 18/997,243

(22) PCT Filed: Nov. 30, 2022
(86) PCT No.: PCT/JP2022/044199

§ 371 Date: Jan. 21, 2025

(51) Int. Cl. H05K 1/02; H01M 10/42; H01M 10/48

(52) U.S. Cl. CPC H05K 1/0216; H01M 10/4257; H01M 10/482; H05K 2201/094; H05K 2201/09418; H05K 2201/10098

(57) ABSTRACT

An electronic substrate unit that is accommodated inside a housing of a battery pack includes an electronic substrate on which a circuit is formed, and a wireless module mounted on the electronic substrate, in which the electronic substrate includes a plurality of attachment portions of the wireless module, and the wireless module is provided on the electronic substrate in a one-on-one manner, and is attached to one of the plurality of attachment portions.

### CROSS REFERENCE TO RELATED APPLICATIONS

This is the U.S. national stage of application No. PCT/JP2022/044199, filed on Nov. 30, 2022, the entire contents of which being incorporated herein by reference.

### TECHNICAL FIELD

The present invention relates to an electronic substrate unit and a battery monitoring system.

### BACKGROUND ART

For example, Patent Document 1 discloses a storage battery device. In the storage battery device disclosed in Patent Document 1, communication between a battery module and a battery management unit is wireless. In a case where the battery module or the battery management unit is housed in a metal housing, radio waves used for communication are reflected in the housing. Interference between the radio waves reflected in this way may cause degradation in communication quality. The storage battery device disclosed in Patent Document 1 includes a battery management unit provided with a plurality of wireless transmission/reception modules. The storage battery device disclosed in Patent Document 1 includes the battery management unit including the plurality of wireless transmission/reception modules, and thus reduces the degradation in communication quality.

### CITATION LIST

### Patent Document

Patent Document 1: PCT International Publication No. WO2021/053722

### SUMMARY OF INVENTION

### Technical Problem

For example, degradation in communication quality due to interference of radio waves in a battery pack such as the storage battery device of Patent Document 1 can be reduced by providing a plurality of antennas for an electronic substrate provided in each battery module or an electronic substrate provided in a battery management unit. For example, the plurality of antennas can be provided on the electronic substrate by providing a plurality of wireless modules including one antenna on the electronic substrate. In addition, the plurality of antennas can be provided on the electronic substrate by providing a wireless module including the plurality of antennas on the electronic substrate. However, providing the plurality of wireless modules on the electronic substrate or providing the plurality of antennas on the wireless module causes complication of an assembly process or an increase in device cost.

The present invention has been made in view of the above-described problems, and an object of the present invention is to reduce degradation in communication quality due to interference of radio waves without providing a plurality of antennas in an electronic substrate unit accommodated inside a housing of a battery pack.

### Solution to Problem

The present invention adopts the following configuration as means for solving the above problems.

An aspect of the present invention adopts a configuration of an electronic substrate unit that is accommodated inside a housing of a battery pack, the electronic substrate unit including an electronic substrate on which a circuit is formed, and a wireless module mounted on the electronic substrate, in which the electronic substrate includes a plurality of attachment portions of the wireless module, and the wireless module is provided on the electronic substrate in a one-on-one manner, and is attached to one of the plurality of attachment portions.

### Advantageous Effects of Invention

The present invention has an electronic substrate in which a plurality of attachment portions of a wireless module are provided.

Therefore, the wireless module can be installed by selecting the attachment portion where an intensity of a radio wave related to communication is high. That is, in the present invention, an installation position of the wireless module can be selected such that a null point at which the radio wave intensity decreases is not generated in a specific use band. Therefore, in the present invention, it is possible to reduce degradation in communication quality due to interference of radio waves without providing a plurality of antennas in an electronic substrate unit accommodated inside a housing of a battery pack.

### BRIEF DESCRIPTION OF DRAWINGS

FIG. 1 An exploded perspective view showing a schematic configuration of a battery pack according to a first embodiment of the present invention.

FIG. 2 A block diagram showing a schematic configuration of a battery monitoring system S according to the first embodiment of the present invention.

FIG. 3 A block diagram including a voltage measurement device A and a monitoring device B included in a battery monitoring system according to the first embodiment of the present invention.

FIG. 4 A schematic view of a voltage measurement device according to the first embodiment of the present invention.

FIG. 5 A schematic view of an electronic substrate included in the voltage measurement device according to the first embodiment of the present invention.

FIG. 6 A schematic cross-sectional view of a printed substrate included in the voltage measurement device according to the first embodiment of the present invention.

FIG. 7A and FIG. 7B A schematic configuration diagram of a wireless module according to the first embodiment of the present invention, in which FIG. 7A is a view showing a front side of the wireless module, and FIG. 7B is a view showing a back side of the wireless module.

FIGS. 8A to FIG. 8C A schematic view showing a disposition relationship between a forward attachment portion and a leftward attachment portion according to the first embodiment of the present invention, in which FIG. 8A is a view showing a state where the forward attachment portion and the leftward attachment portion are disposed to overlap each other, FIG. 8B is a view showing the forward attachment portion, and FIG. 8C is a view showing the leftward attachment portion.

FIG. 9A and FIG. 9B An enlarged view of the wireless module attached to the electronic substrate of the voltage measurement device according to the first embodiment of the present invention, in which FIG. 9A is an enlarged view of the wireless module attached to the electronic substrate in a forward direction, and FIG. 9B is an enlarged view of the wireless module attached to the electronic substrate in a leftward direction.

FIG. 10 A schematic enlarged view of a portion of the electronic substrate of the voltage measurement device according to the first embodiment of the present invention, in which the forward attachment portion and the leftward attachment portion are provided.

FIG. 11 A schematic view showing a second conductor layer of the printed substrate according to the first embodiment of the present invention.

FIG. 12 A schematic view showing a third conductor layer of the printed substrate according to the first embodiment of the present invention.

FIG. 13 A schematic view of an electronic substrate included in a monitoring device according to the first embodiment of the present invention.

FIG. 14 A schematic view of an electronic substrate included in a voltage measurement device according to a second embodiment of the present invention.

FIG. 15 A schematic view of an electronic substrate included in a monitoring device according to the second embodiment of the present invention.

FIG. 16 A diagram schematically showing a front surface side of a wireless module according to a third embodiment of the present invention.

FIG. 17 An enlarged schematic view of part of an electronic substrate of a voltage measurement device according to the third embodiment of the present invention.

### DESCRIPTION OF EMBODIMENTS

Hereinafter, an embodiment of an electronic substrate unit and a battery monitoring system according to the present invention will be described with reference to the drawings.

### First Embodiment

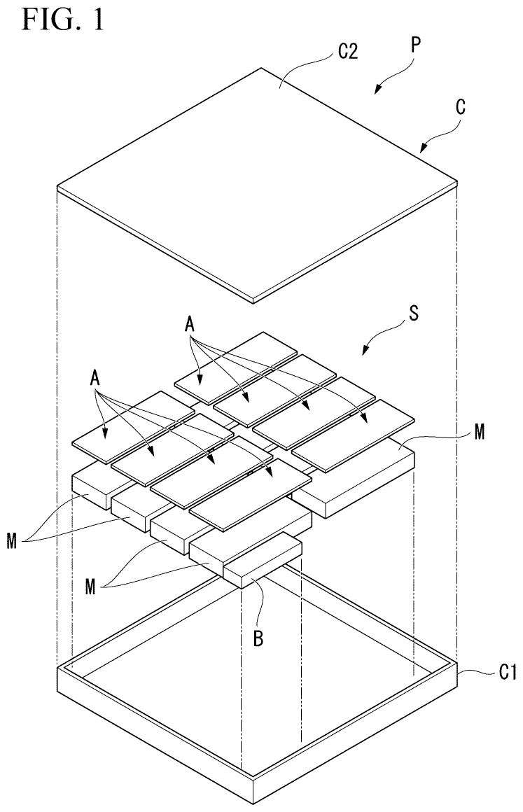

FIG. 1 is an exploded perspective view showing a schematic configuration of a battery pack P according to the present embodiment. The battery pack P is mounted on a vehicle such as an electric vehicle or a hybrid vehicle, or the like. As shown in FIG. 1, the battery pack P includes a housing C, a plurality of battery modules M, and a battery monitoring system S according to the present embodiment. In addition, the battery pack P includes a connector or a contactor (not shown).

The housing C is a metal container that accommodates a plurality of battery modules M and the battery monitoring system S. For example, as shown in FIG. 1, the housing C includes a box-shaped container main body portion C1 of which a part is open and a lid portion C2 that closes an opening portion of the container main body portion C1. However, a shape of the housing C is not limited to a shape shown in FIG. 1, and may be any shape as long as the plurality of battery modules M and the battery monitoring system S can be accommodated.

Each battery module M includes a plurality of battery cells connected in series or in parallel. A total voltage of the battery cells is set as an output voltage of each battery module M. The plurality of battery modules M are connected in series and accommodated inside the housing C. The battery pack P shown in FIG. 1 includes eight battery modules M. However, the number of battery modules M included in the battery pack P can be changed.

Each of the battery modules M is, for example, a battery that stores power for driving a vehicle such as an electric vehicle or a hybrid vehicle, or the like and is a secondary battery such as a lithium-ion battery or a nickel hydrogen battery, or the like. In addition, a fuel cell can also be used as the battery module M in addition to the above-described lithium-ion battery or nickel hydrogen battery. The battery pack P including a plurality of such battery modules M outputs, for example, an output voltage of several hundred volts.

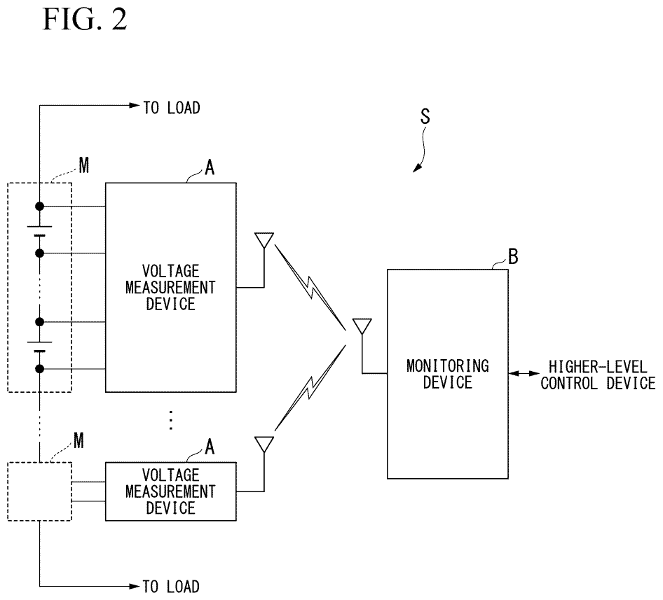

The battery monitoring system S according to the present embodiment monitors the voltage and the like of each battery module M of the battery pack P. In addition, the battery monitoring system S according to the present embodiment adjusts the voltage of the battery cell included in the battery module M as necessary. FIG. 2 is a block diagram showing a schematic configuration of the battery monitoring system S according to the present embodiment.

As shown in FIG. 2, the battery monitoring system S according to the present embodiment includes a plurality of voltage measurement devices A (electronic substrate units) and a single monitoring device B (electronic substrate unit). The voltage measurement device A and the monitoring device B are wirelessly connected to each other by a predetermined wireless line.

The plurality of voltage measurement devices A are provided to correspond to each of the battery modules M. That is, the same number of voltage measurement devices as the number of the battery modules M are provided. Each voltage measurement device A detects the voltage of the battery module M corresponding to each voltage measurement device A (the voltage of each battery cell) and wirelessly transmits a voltage detection value thereof to the monitoring device B.

The monitoring device B monitors a state of the battery module M based on the voltage detection value of each battery module M wirelessly received from each voltage measurement device A. The monitoring device B sequentially reports a monitoring result of the battery module M to a higher-level control device (not shown).

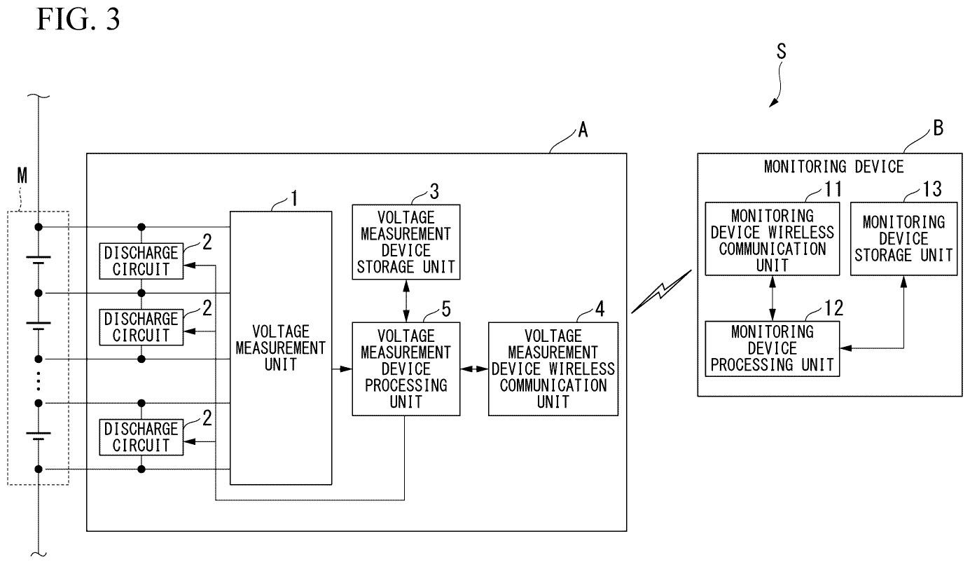

The voltage measurement device A and the monitoring device B as above will be described in more detail with reference to FIG. 3. It should be noted that, although each voltage measurement device A is assigned individual identification information for specifying its own disposition position, the basic configuration is the same.

FIG. 3 is a block diagram including the voltage measurement device A and the monitoring device B included in the battery monitoring system S according to the present embodiment. As shown in the diagram, the voltage measurement device A includes a voltage measurement unit 1, a plurality of discharge circuits 2, a voltage measurement device storage unit 3, a voltage measurement device wireless communication unit 4, and a voltage measurement device processing unit 5.

The voltage measurement unit 1 detects an output voltage (cell voltage) of each battery cell constituting the battery module M, and outputs a detection value of each cell voltage (cell voltage detection value) to the voltage measurement device processing unit 5. In the voltage measurement unit 1, as shown in the drawing, each of electrodes (a positive electrode and a negative electrode) of each battery cell in the battery module M is connected to each of a plurality of input terminals. The voltage measurement unit 1 acquires the cell voltage detection value for each battery cell based on a difference between a potential of the positive electrode and a potential of the negative electrode.

The voltage measurement unit 1 detects a cell voltage, which is an analog value, by sampling the potential of the positive electrode and the potential of the negative electrode of each battery cell at a predetermined time interval. In addition, the voltage measurement unit 1 sequentially outputs the cell voltage detection value to the voltage measurement device processing unit 5.

As described above, each battery module M is a secondary battery and can perform discharging and charging. Each discharge circuit 2 is provided for respective one of the battery cells of the battery module M and is a series circuit for equalizing a charging state thereof. Each discharge circuit 2 is a circuit in which an electronic switch and a resistor provided for each battery cell are connected in series.

Each of the discharge circuits 2 includes an electronic switch such as a switching transistor or the like of which an on-state and an off-state are operated by the voltage measurement device processing unit 5. In addition, the voltage measurement device processing unit 5 includes a resistor that is connected in series with the electronic switch and has a predetermined resistance value. The electronic switch of the discharge circuit 2 corresponding to each battery cell is switched between the on-state and the off-state by the voltage measurement device processing unit 5. In a case where the electronic switch of the discharge circuit 2 is turned to the on-state, power of the battery cell is discharged.

The voltage measurement device storage unit 3 is, for example, a rewritable non-volatile memory or the like. The voltage measurement device storage unit 3 stores the cell voltage measured by the voltage measurement unit 1, a program or a parameter or the like required for processing of the voltage measurement device processing unit 5.

The voltage measurement device wireless communication unit 4 transmits and receives information by performing wireless communication with the monitoring device B. The voltage measurement device wireless communication unit 4 receives the information obtained from the monitoring device B via wireless communication and outputs the information to the voltage measurement device processing unit 5. In addition, the voltage measurement device wireless communication unit 4 transmits the information from the voltage measurement device processing unit 5 to the monitoring device B via wireless communication. A communication method of the wireless communication is not particularly limited as long as it is wireless.

The voltage measurement device processing unit 5 executes cell balance control by controlling the discharge circuit 2 based on the plurality of cell voltages acquired from the voltage measurement unit 1. In addition, the voltage measurement device processing unit 5 transmits information necessary for stably operating the battery module M (hereinafter, referred to as “management information”) to the monitoring device B via wireless communication. The management information is, for example, information indicating the plurality of cell voltages, a maximum cell voltage, and a minimum cell voltage.

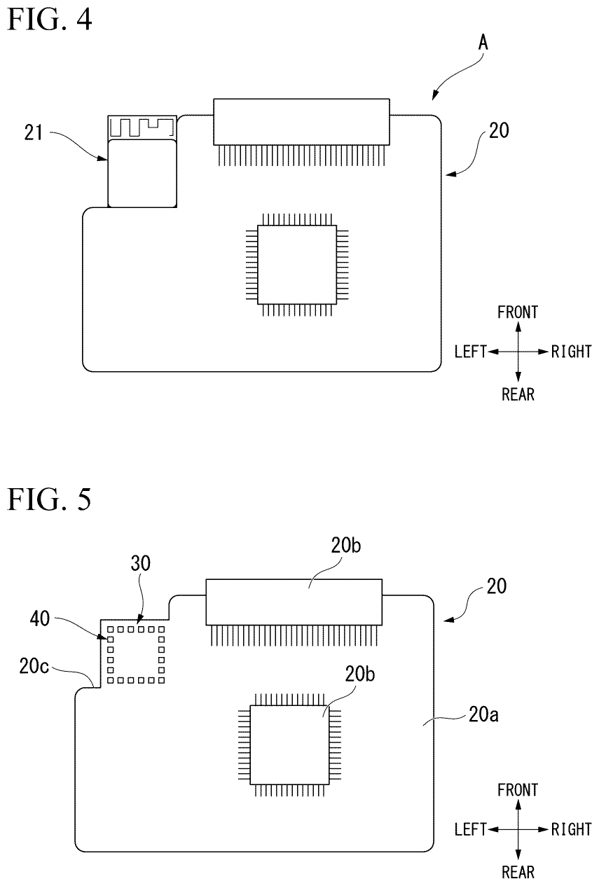

FIG. 4 is a schematic view of the voltage measurement device A. As shown in FIG. 4, in the present embodiment, the voltage measurement device A is an electronic substrate unit including an electronic substrate 20 and a wireless module 21. As shown in FIG. 4, in the voltage measurement device A, the wireless module 21 is mounted on the electronic substrate 20.

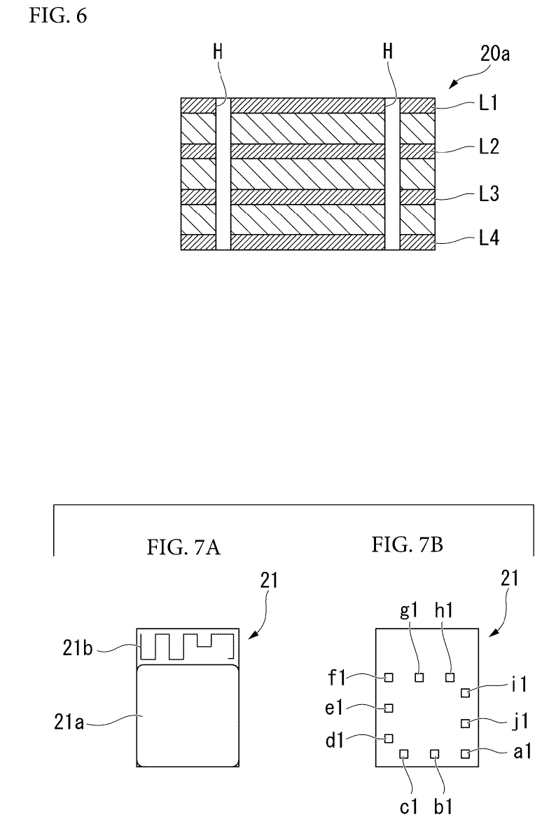

FIG. 5 is a schematic view of the electronic substrate 20. The electronic substrate 20 is a substrate on which a circuit is formed and has a printed substrate 20a and an electronic component 20b. The printed substrate 20a is a multilayer substrate provided with a plurality of conductor layers. FIG. 6 is a schematic cross-sectional view of the printed substrate 20a. As shown in the view, the printed substrate 20a according to the present embodiment has four conductor layers (a first conductor layer L1, a second conductor layer L2, a third conductor layer L3, and a fourth conductor layer L4). The number of conductor layers of the printed substrate 20a can be changed.

For convenience of description, among the four conductor layers, the conductor layer located closest to a substrate front side is referred to as the first conductor layer L1, and the conductor layer located closest to a substrate back side is referred to as the fourth conductor layer L4. In addition, among the two interlayers located between the first conductor layer L1 and the fourth conductor layer L4, the conductor layer on a first conductor layer L1 side is referred to as the second conductor layer L2, and the conductor layer on a fourth conductor layer L4 side is referred to as the third conductor layer L3.

In addition, the printed substrate 20a has a plurality of through-holes H that electrically connect a plurality of conductor layers. Through these through-holes H, the conductor layer is connected to another conductor layer. The printed substrate 20a may have a via that does not penetrate the printed substrate 20a, instead of the through-hole H or in addition to the through-hole H.

The electronic component 20b is, for example, a processor such as a central processing unit (CPU) or a micro processing unit (MPU). In addition, the electronic component 20b is a non-volatile or volatile semiconductor memory (for example, a random-access memory (RAM), a read-only memory (ROM), a flash memory, an erasable programmable read-only memory (EPROM), or an electrically erasable programmable read-only memory (EEPROM)).

One wireless module 21 is provided on one electronic substrate 20. In the present embodiment, the wireless module 21 functions as the voltage measurement device wireless communication unit 4 described above. FIG. 7A and FIG. 7B are schematic configuration diagrams of the wireless module 21, in which FIG. 7A is a view showing a front side of the wireless module 21, and FIG. 7B is a view showing a back side of the wireless module 21.

As shown in FIG. 7A and FIG. 7B, the wireless module 21 includes a wireless IC chip 21a and one antenna portion 21b. The wireless IC chip 21a is an integrated circuit (IC) chip that processes a signal transmitted and received by the antenna portion 21b. The wireless IC chip 21a is formed in a square shape as shown in FIG. 7A and FIG. 7B. The antenna portion 21b is provided to protrude from one side of the square wireless IC chip 21a toward a side direction of the wireless IC chip 21a. The antenna portion 21b consists of a single antenna element.

A direction in which the antenna portion 21b protrudes when viewed from the wireless IC chip 21a is defined as an orientation of the wireless module 21. For example, in a case where the antenna portion 21b is mounted on the electronic substrate 20 such that the antenna portion 21b faces a front side of the electronic substrate 20 when viewed from the wireless IC chip 21a, the orientation of the wireless module 21 is forward.

As shown in part (b) of FIG. 7, a plurality of terminals (terminals a1 to j1) are provided on a back surface side of the wireless IC chip 21a. In the present embodiment, ten terminals are provided for the wireless IC chip 21a. However, the number of terminals provided in the wireless IC chip 21a can be changed. For convenience of description, the ten terminals are referred to as the terminals a1 to j1. As shown in part (b) of FIG. 7, the terminals a1 to j1 are arranged to draw a square (rectangle). That is, the terminals a1 to j1 are arranged in a pattern in a square shape.

Returning to FIG. 5, the electronic substrate 20 includes attachment portions (forward attachment portion 30 and leftward attachment portion 40) of the wireless module 21. An installation posture of the electronic substrate 20 is not particularly limited, but for convenience of description, as shown in FIG. 5, one direction is referred to as a front-rear direction, and a direction orthogonal to the front-rear direction is referred to as a left-right direction.

The electronic substrate 20 has a forward attachment portion 30 (first attachment portion) in which the wireless module 21 is forward in a case where the wireless module 21 is attached, and a leftward attachment portion 40 (second attachment portion) in which the wireless module 21 is leftward in a case where the wireless module 21 is attached.

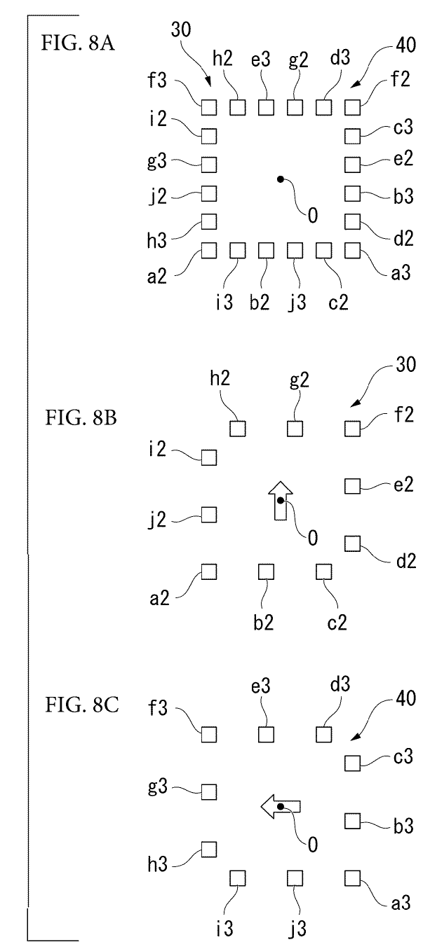

Each of the forward attachment portion 30 and the leftward attachment portion 40 includes a plurality of pads. FIGS. 8A to FIG. 8C are schematic views showing a disposition relationship between the forward attachment portion 30 and the leftward attachment portion 40, in which FIG. 8A shows a state where the forward attachment portion 30 and the leftward attachment portion 40 are disposed to overlap each other, FIG. 8B shows the forward attachment portion 30, and FIG. 8C shows the leftward attachment portion 40.

As shown in FIG. 8B, the forward attachment portion 30 includes the same number of pads (pads a2 to j2) as the number of the terminals of the wireless module 21. The pads are terminal connection portions for connecting the wireless module 21 and are formed of part of the first conductor layer L1. In the present embodiment, since ten terminals of the wireless module 21 are provided, ten pads of the forward attachment portion 30 are also provided. For convenience of description, the ten pads are referred to as the pads a2 to j2 (terminal connection portions). As shown in FIG. 8B, the pads a2 to j2 are arranged to draw a square (rectangle) similarly to the terminals a1 to j1 of the wireless module 21. That is, the terminals al to j1 are arranged in the pattern in the square shape.

In a case where the wireless module 21 is attached to the electronic substrate 20 in a forward direction, the terminals a1 to j1 are connected to the pads a2 to j2 of the forward attachment portion 30. In this case, the terminals a1 to j1 are joined to the pads a2 to j2 using a brazing material such as solder. The pad a2 is a terminal connection portion to which the terminal a1 is connected. The pad b2 is a terminal connection portion to which the terminal b1 is connected. The pad c2 is a terminal connection portion to which the terminal c1 is connected. The pad d2 is a terminal connection portion to which the terminal d1 is connected. The pad e2 is a terminal connection portion to which the terminal e1 is connected. The pad f2 is a terminal connection portion to which the terminal f1 is connected. The pad g2 is a terminal connection portion to which the terminal g1 is connected. The pad h2 is a terminal connection portion to which the terminal h1 is connected. The pad i2 is a terminal connection portion to which the terminal i1 is connected. The pad j2 is a terminal connection portion to which the terminal j1 is connected.

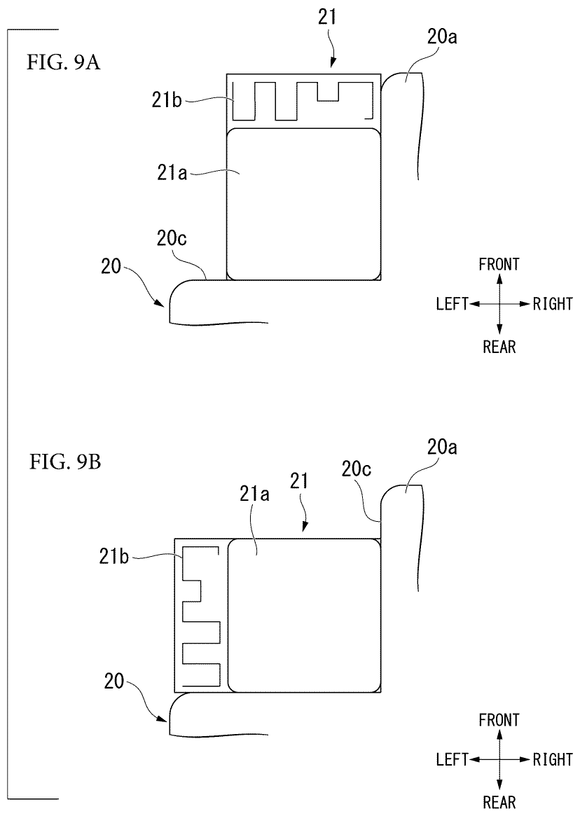

FIG. 9A and FIG. 9B is an enlarged view of the wireless module 21 attached to the electronic substrate 20, in FIG. 9A is an enlarged view of the wireless module 21 attached to the electronic substrate 20 in the forward direction, and FIG. 9B is an enlarged view of the wireless module 21 attached to the electronic substrate 20 in a leftward direction. In a case where the wireless module 21 is attached to the forward attachment portion 30, the wireless module 21 is mounted such that the antenna portion 21b of the wireless module 21 is located on a front side with respect to the wireless IC chip 21a as shown FIG. 9A. That is, the orientation of the wireless module 21 attached to the forward attachment portion 30 is forward as indicated by an arrow in FIG. 8B.

As shown in FIG. 8C, the leftward attachment portion 40 has the same number of pads (pads a3 to j3) as the number of the terminals of the wireless module 21. The pads are terminal connection portions for connecting the wireless module 21 and are formed of part of the first conductor layer L1. In the present embodiment, since ten terminals of the wireless module 21 are provided, ten pads of the leftward attachment portion 40 are also provided. For convenience of description, the ten pads are referred to as the pads a3 to j3 (terminal connection portions). As shown in FIG. 8C, the pads a3 to j3 are arranged to draw a square (rectangle) similarly to the terminals a1 to j1 of the wireless module 21. That is, the terminals a1 to j1 are arranged in the pattern in the square shape.

In a case where the wireless module 21 is attached to the electronic substrate 20 in the leftward direction, the terminals a1 to j1 are connected to the pads a3 to j3 of the leftward attachment portion 40. In this case, the terminals a1 to j1 are joined to the pads a3 to j3 using a brazing material such as solder. The pad a3 is a terminal connection portion to which the terminal a1 is connected. The pad b3 is a terminal connection portion to which the terminal b1 is connected. The pad c3 is a terminal connection portion to which the terminal c1 is connected. The pad d3 is a terminal connection portion to which the terminal d1 is connected. The pad e3 is a terminal connection portion to which the terminal e1 is connected. The pad f3 is a terminal connection portion to which the terminal f1 is connected. The pad g3 is a terminal connection portion to which the terminal g1 is connected. The pad h3 is a terminal connection portion to which the terminal h1 is connected. The pad i3 is a terminal connection portion to which the terminal i1 is connected. The pad j3 is a terminal connection portion to which the terminal j1 is connected.

In a case where the wireless module 21 is attached to the leftward attachment portion 40, the wireless module 21 is mounted such that the antenna portion 21b of the wireless module 21 is located on a left side with respect to the wireless IC chip 21a as shown in FIG. 9B. That is, the orientation of the wireless module 21 attached to the leftward attachment portion 40 is leftward as indicated by an arrow in FIG. 8C.

The pads a2 to j2 of the forward attachment portion 30 and the pads a3 to j3 of the leftward attachment portion 40 are all connected to the terminals a1 to j1 of the wireless module 21.

Therefore, the pads a2 to j2 of the forward attachment portion 30 and the pads a3 to j3 of the leftward attachment portion 40 are arranged to draw patterns in square shapes having the same size. The pads a3 to j3 of the leftward attachment portion 40 are disposed at positions that do not overlap the pads a2 to j2 of the forward attachment portion 30 in a case where the pads a2 to j2 of the forward attachment portion 30 are rotated by 90° to the left side with a center O of the square shape as a center.

As shown in of FIG. 8A, the voltage measurement device A of the present embodiment includes the forward attachment portion 30 and the leftward attachment portion 40 that are provided at the same position in the electronic substrate 20 such that the center O of the square drawn by the pads a2 to j2 of the forward attachment portion 30 and the center O of the square drawn by the a3 to j3 of the leftward attachment portion 40 overlap each other. In the present embodiment, as shown in FIG. 5, the forward attachment portion 30 and the leftward attachment portion 40 are provided on a left front side portion of the electronic substrate 20 to overlap each other. That is, in the present embodiment, the forward attachment portion 30 and the leftward attachment portion 40 are disposed to overlap each other when viewed from a normal direction of the electronic substrate 20 (a direction orthogonal to the front-rear direction and the left-right direction).

The wireless module 21 is attached to any of the forward attachment portion 30 or the leftward attachment portion 40 described above. That is, in the voltage measurement device A according to the present embodiment, one wireless module 21 is provided on the electronic substrate 20 and is attached to any one of the plurality of attachment portions provided on the electronic substrate 20.

In addition, the electronic substrate 20 has a notch portion 20c provided at a position with a possibility of facing the antenna portion 21b of the wireless module 21 in a case where the wireless module 21 is mounted. In the present embodiment, the wireless module 21 can be mounted on the electronic substrate 20 in the forward direction and the leftward direction. Therefore, the notch portion 20c is provided such that part of the electronic substrate 20 does not face a portion facing the antenna portion 21b in a case where the wireless module 21 is forward, and a portion facing the antenna portion 21b in a case where the wireless module 21 is leftward. The notch portion 20c as above prevents part of the electronic substrate 20 from facing a back surface of the antenna portion 21b of the wireless module 21. Therefore, the voltage measurement device A can prevent part of the electronic substrate 20 from shielding radio waves incident on the antenna portion 21b or radio waves emitted from the antenna portion 21b and can improve communication quality.

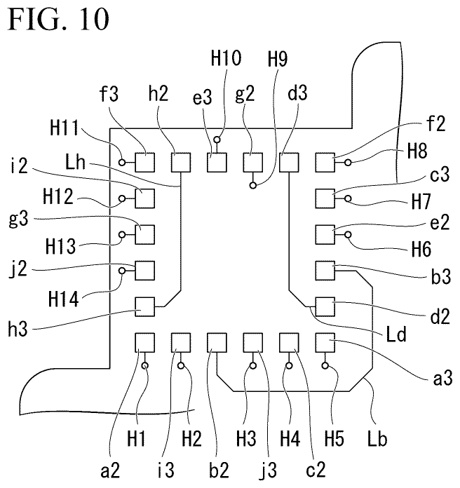

FIG. 10 is a schematic enlarged view of a portion of the electronic substrate 20, in which the forward attachment portion 30 and the leftward attachment portion 40 are provided. As shown in the view, the electronic substrate 20 includes a plurality of through-holes (H1 to H13) connected to the pads. The through-hole H1 is connected to the pad a2. The through-hole H2 is connected to the pad i3. The through-hole H3 is connected to the pad j3. The through-hole H4 is connected to the pad c2. The through-hole H5 is connected to the pad a3. The through-hole H6 is connected to the pad e2. The through-hole H7 is connected to the pad c3. The through-hole H8 is connected to the pad f2. The through-hole H9 is connected to the pad g2. The through-hole H10 is connected to the pad e3. The through-hole H11 is connected to the pad f3. The through-hole H12 is connected to the pad i2. The through-hole H13 is connected to the pad j2.

In addition, as shown in FIG. 10, the pad b2 and the pad b3 are connected to each other via a connection line Lb. In addition, the pad d2 and the pad d3 are connected to each other via a connection line Ld. In addition, the pad h2 and the pad h3 are connected to each other via a connection line Lh. The connection line Lb, connection line Ld, and connection line Lh are formed of part of the first conductor layer L1.

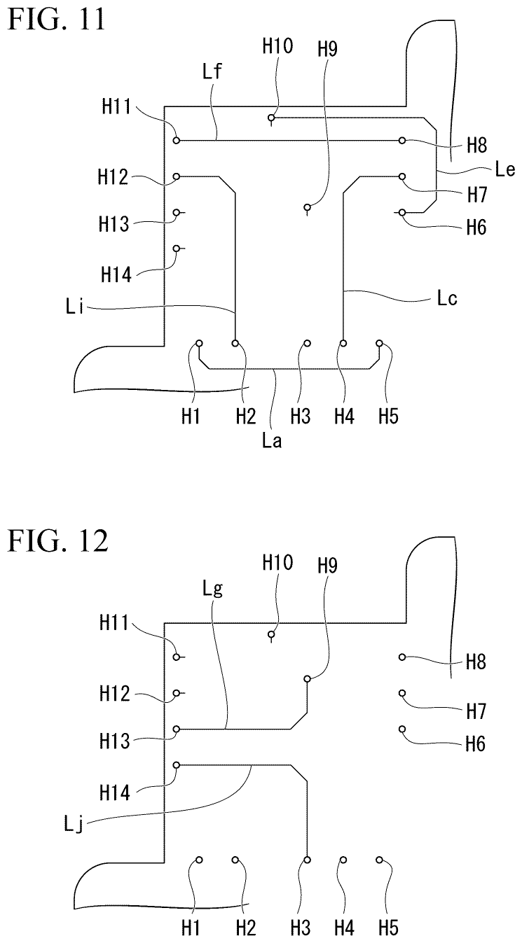

FIG. 11 is a schematic view showing the second conductor layer L2 of the printed substrate 20a. As shown in the view, the through-hole H4 and the through-hole H7 are connected to each other via a connection line Lc. That is, the pad c2 and the pad c3 shown in FIG. 10 are connected to each other via the connection line Lc.

In addition, as shown in FIG. 11, the through-hole H6 and the through-hole H10 are connected to each other via a connection line Le. That is, the pad e2 and the pad e3 shown in FIG. 10 are connected to each other via the connection line Le.

In addition, as shown in FIG. 11, the through-hole H8 and the through-hole H11 are connected to each other via a connection line Lf. That is, the pad f2 and the pad f3 shown in FIG. 11 are connected to each other via the connection line Lf.

In addition, as shown in FIG. 11, the through-hole H2 and the through-hole H12 are connected to each other via a connection line Li. That is, the pad i2 and the pad i3 shown in FIG. 10 are connected to each other via the connection line Li.

FIG. 12 is a schematic view showing the third conductor layer L3 of the printed substrate 20a. As shown in the view, the through-hole H9 and the through-hole H13 are connected to each other via a connection line Lg. That is, the pad g2 and the pad g3 shown in FIG. 10 are connected to each other via the connection line Lg.

In addition, as shown in FIG. 12, the through-hole H3 and the through-hole H14 are connected to each other via a connection line Lj. That is, the pad j2 and the pad j3 shown in FIG. 10 are connected to each other via the connection line Lj.

The connection line Lc, the connection line Le, the connection line Lf, and the connection line Li shown in FIG. 11 are formed of part of the second conductor layer L2. In addition, the connection line Lg and the connection line Lj shown in FIG. 12 are formed of part of the third conductor layer L3.

As described above, in the present embodiment, in the forward attachment portion 30 and the leftward attachment portion 40, pads to which the same terminal of the wireless module 21 is connected are electrically connected. That is, the pad a2 of the forward attachment portion 30 is electrically connected to the pad a3 of the leftward attachment portion 40. In addition, the pad b2 of the forward attachment portion 30 is electrically connected to the pad b3 of the leftward attachment portion 40. In addition, the pad c2 of the forward attachment portion 30 is electrically connected to the pad c3 of the leftward attachment portion 40. In addition, the pad d2 of the forward attachment portion 30 is electrically connected to the pad d3 of the leftward attachment portion 40. In addition, the pad e2 of the forward attachment portion 30 is electrically connected to the pad e3 of the leftward attachment portion 40. In addition, the pad f2 of the forward attachment portion 30 is electrically connected to the pad f3 of the leftward attachment portion 40. In addition, the pad g2 of the forward attachment portion 30 is electrically connected to the pad g3 of the leftward attachment portion 40. In addition, the pad h2 of the forward attachment portion 30 is electrically connected to the pad h3 of the leftward attachment portion 40. In addition, the pad i2 of the forward attachment portion 30 is electrically connected to the pad i3 of the leftward attachment portion 40. In addition, the pad j2 of the forward attachment portion 30 is electrically connected to the pad j3 of the leftward attachment portion 40.

In the voltage measurement device A according to the present embodiment as above, the leftward attachment portion 40 is provided at a position where the forward attachment portion 30 is rotated by 90° counterclockwise with the position of the center O as a center, and the pads a3 to j3 of the leftward attachment portion 40 are electrically connected to the pads a2 to j2 of the forward attachment portion 30 at a position where the pads a2 to j2 are rotated by 90° with the position of the center O as a center. Therefore, the wireless module 21 is electrically connected to the electronic substrate 20 in the same manner even in a case where the wireless module 21 is attached to any one of the forward attachment portion 30 or the leftward attachment portion 40.

Returning to FIG. 2, the monitoring device B transmits and receives information by performing wireless communication with each of the plurality of voltage measurement devices A, and manages the plurality of battery modules M. The monitoring device B communicates with each of the plurality of voltage measurement devices A and receives management information of each battery module M. The monitoring device B figures out the state of each battery module M based on the management information. For example, the monitoring device B is a battery management unit (BMU). As shown in FIG. 3, the monitoring device B as above includes a monitoring device wireless communication unit 11, a monitoring device processing unit 12, and a monitoring device storage unit 13.

The monitoring device wireless communication unit 11 performs wireless communication with the voltage measurement device wireless communication unit 4 of the voltage measurement device A to transmit and receive information. The monitoring device wireless communication unit 11 receives the information obtained from the voltage measurement device wireless communication unit 4 of the voltage measurement device A via wireless communication and outputs the information to the monitoring device processing unit 12. In addition, the monitoring device wireless communication unit 11 transmits the information from the monitoring device processing unit 12 to the voltage measurement device wireless communication unit 4 via wireless communication.

The monitoring device processing unit 12 acquires the management information obtained from the voltage measurement device A via wireless communication. For example, the monitoring device processing unit 12 determines, for example, whether or not each battery module M is normal, based on the management information obtained from the voltage measurement device A. In addition, in order to prevent the communication between the monitoring device B and each voltage measurement device A from being mixed, the wireless communication between the monitoring device B and each voltage measurement device A is scheduled by a timer or the like.

The monitoring device storage unit 13 is a rewritable non-volatile memory or the like. The monitoring device storage unit 13 stores, for example, a program or a parameter for causing the monitoring device processing unit 12 to execute processing.

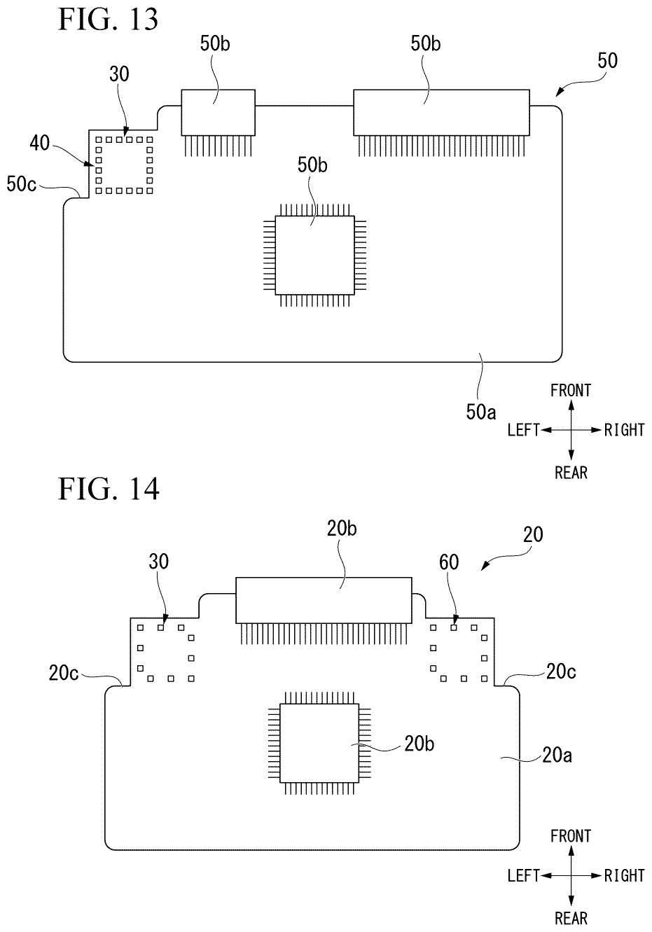

The monitoring device B is an electronic substrate unit including an electronic substrate and a wireless module, similarly to each voltage measurement device A. FIG. 13 is a schematic view of an electronic substrate 50 included in the monitoring device B. Since the wireless module included in the monitoring device B has the same configuration as the wireless module of the voltage measurement device A, the description thereof will be omitted here.

The electronic substrate 50 is a substrate on which a circuit is formed and includes a printed substrate 50a and an electronic component 50b. The printed substrate 50a is a multilayer substrate provided with a plurality of conductor layers, similarly to the printed substrate 20a of the voltage measurement device A. In addition, the printed substrate 50a includes a plurality of through-holes that electrically connect a plurality of conductor layers. The printed substrate 50a may have a via that does not penetrate the printed substrate 50a, instead of the through-hole or in addition to the through-hole.

The electronic component 50b is, for example, a processor such as a CPU or an MPU. In addition, the electronic component 50b is a non-volatile or volatile semiconductor memory (for example, a RAM, a ROM, a flash memory, an EPROM, or an EEPROM).

The electronic substrate 50 as above includes the attachment portions (the forward attachment portion 30 and the leftward attachment portion 40) of the wireless module. An installation posture of the electronic substrate 50 is not particularly limited, but for convenience of description, as shown in FIG. 13, one direction is referred to as a front-rear direction, and a direction orthogonal to the front-rear direction is referred to as a left-right direction. The electronic substrate 50 includes the forward attachment portion 30 (first attachment portion) in which the wireless module is forward in a case where the wireless module is attached, and the leftward attachment portion 40 (second attachment portion) in which the wireless module is leftward in a case where the wireless module is attached. In the present embodiment, as shown in FIG. 5, the forward attachment portion 30 and the leftward attachment portion 40 are provided on a left front side portion of the electronic substrate 50 to overlap each other.

In addition, the electronic substrate 50 includes a notch portion 50c provided at a position with a possibility of facing the antenna portion 21b of the wireless module in a case where the wireless module is mounted. In the present embodiment, the wireless module can be mounted on the electronic substrate 20 in a forward direction and a leftward direction. Therefore, the notch portion 50c is provided such that part of the electronic substrate 50 does not face a portion facing the antenna portion 21b in a case where the wireless module is forward, and a portion facing the antenna portion 21b in a case where the wireless module is leftward.

In the voltage measurement device A of the present embodiment as above, an attachment position of the wireless module 21 is selected such that a null point at which the radio wave intensity decreases is not generated in a specific use band at the position of the antenna portion 21b of the wireless module 21 based on an experiment or a simulation. Specifically, any one of the forward attachment portion 30 or the leftward attachment portion 40 is selected as the attachment position of the wireless module 21. For example, the generation of the null point in the specific use band used by the wireless module 21 is detected by performing an experiment or a simulation in a state where the wireless module 21 is attached to the forward attachment portion 30. In a case where the null point is generated at the position of the antenna portion 21b of the wireless module 21, the leftward attachment portion 40 is selected as the attachment portion of the wireless module 21. In addition, in a case where the null point is generated in both cases where the forward attachment portion 30 is used and where the leftward attachment portion 40 is used, the one having a higher radio wave intensity is selected.

In addition, even in the case of the monitoring device B according to the present embodiment, the attachment position of the wireless module is selected such that the null point is not generated in the specific use band at the position of the antenna portion of the wireless module based on an experiment or a simulation. Specifically, any of the forward attachment portion 30 and the leftward attachment portion 40 is selected as the attachment position of the wireless module. For example, the generation of the null point in the specific use band used by the wireless module is detected by performing an experiment or a simulation in a state where the wireless module is attached to the forward attachment portion 30. In a case where the null point is generated at the position of the antenna portion of the wireless module, the leftward attachment portion 40 is selected as the attachment portion of the wireless module. In addition, in a case where the null point is generated in both cases where the forward attachment portion 30 is used and where the leftward attachment portion 40 is used, the one having a higher radio wave intensity is selected.

The voltage measurement device A according to the present embodiment as above includes the electronic substrate 20 on which a circuit is formed and the wireless module 21. The wireless module 21 is mounted on the electronic substrate 20. In addition, the voltage measurement device A is accommodated inside the housing C of the battery pack P. In addition, the electronic substrate 20 includes the plurality of attachment portions (forward attachment portion 30 and leftward attachment portion 40) of the wireless module 21. One wireless module 21 is provided on one electronic substrate 20 and is attached to any one of the plurality of attachment portions.

In the voltage measurement device A according to the present embodiment as above, the wireless module 21 can be installed by selecting the attachment portion where an intensity of a radio wave related to communication is high. That is, the voltage measurement device A can select an installation position of the wireless module 21 such that the null point is not generated in the specific use band used by the wireless module 21 at the position of the antenna portion 21b of the wireless module 21. Therefore, the voltage measurement device A can reduce degradation in communication quality due to interference of radio waves without providing a plurality of antennas.

In addition, the monitoring device B according to the present embodiment includes the electronic substrate 50 on which a circuit is formed and the wireless module. The wireless module is mounted on the electronic substrate 50. In addition, the monitoring device B is housed inside the housing C of the battery pack P. In addition, the electronic substrate 50 includes the plurality of attachment portions (the forward attachment portion 30 and the leftward attachment portion 40) of the wireless module. One wireless module is provided on one electronic substrate 50 and is attached to any one of the plurality of attachment portions.

In the monitoring device B according to the present embodiment, the wireless module can be installed by selecting the attachment portion where an intensity of a radio wave related to communication is high. That is, the monitoring device B can select the installation position of the wireless module such that the null point is not generated in the specific use band used by the wireless module at the position of the antenna portion of the wireless module. Therefore, the monitoring device B can reduce degradation in communication quality due to interference of radio waves without providing a plurality of antennas.

In addition, in the voltage measurement device A, the electronic substrate 20 includes the forward attachment portion 30 and the leftward attachment portion 40, which are one of the attachment portions. In the leftward attachment portion 40, the orientation of the wireless module 21 when viewed in the normal direction of the electronic substrate 20 in a case where the wireless module 21 is mounted is different from that of the forward attachment portion 30. Further, the forward attachment portion 30 and the leftward attachment portion 40 are disposed on the electronic substrate 20 to overlap each other when viewed in the normal direction.

The voltage measurement device A according to the present embodiment includes the forward attachment portion 30 and the leftward attachment portion 40 that are provided to overlap each other. Therefore, the electronic substrate 20 is reduced in size as compared with a case where the forward attachment portion 30 and the leftward attachment portion 40 are located apart from each other. Therefore, the voltage measurement device A according to the present embodiment is small. In addition, in the monitoring device B according to the present embodiment, the electronic substrate 50 is also reduced in size in the same manner. Therefore, the monitoring device B is small.

In addition, in the voltage measurement device A according to the present embodiment, each of the forward attachment portion 30 and the leftward attachment portion 40 has a plurality of pads to which the terminals a1 to j1 of the wireless module 21 are connected and which are arranged in the same pattern in a rectangular shape. In addition, the pads a2 to j2 of the leftward attachment portion 40 are provided at positions rotated by 90° with respect to the pads a3 to j3 of the forward attachment portion 30 with a center position of the rectangular shape as a center. In addition, each of the pads a3 to j3 of the leftward attachment portion 40 is electrically connected to the pads a2 to j2 of the forward attachment portion 30 at a position rotated by 90° with the position of the center O as a center.

With the voltage measurement device A according to the present embodiment as above, the wireless module 21 is electrically connected to the electronic substrate 20 in the same manner even in a case where the wireless module 21 is attached to any one of the forward attachment portion 30 or the leftward attachment portion 40. Therefore, regardless of which of the attachment portions are selected, the wireless module 21 can be easily connected to the electronic substrate 20. In addition, the monitoring device B can also easily connect the wireless module to the electronic substrate 50 in the same manner.

In addition, the wireless module 21 includes the wireless IC chip 21a including terminals a1 to j1 connected to the electronic substrate 20, and the antenna portion 21b provided to protrude sideways from the wireless IC chip 21a. With the voltage measurement device A according to the present embodiment as above, the orientation of the antenna portion 21b can be easily figured out by visually observing the antenna portion 21b. In addition, the orientation of the wireless module connected to the electronic substrate 50 of the monitoring device B can also be easily figured out.

In addition, in the voltage measurement device A according to the present embodiment, the electronic substrate 20 includes the notch portion 20c provided at a position with a possibility of facing the antenna portion 21b. With the voltage measurement device A according to the present embodiment, it is possible to prevent communication of the antenna portion 21b from being hindered by part of the electronic substrate 20. Therefore, the voltage measurement device A according to the present embodiment can further improve communication quality. In addition, since the monitoring device B also has the notch portion 20c, communication quality can be further improved in the same manner.

In addition, the battery monitoring system S according to the present embodiment includes the plurality of battery modules M, the voltage measurement device A provided in each of the battery modules M, and the monitoring device B that performs wireless communication with the voltage measurement device A. In addition, each of the voltage measurement device A and the monitoring device B includes the plurality of attachment portions of the wireless module 21. Therefore, the battery monitoring system S according to the present embodiment can reduce degradation in communication quality due to interference of radio waves.

In addition, in battery monitoring system S according to the present embodiment, each of the voltage measurement device A and the monitoring device B includes one wireless module. Therefore, the number of wireless modules to be installed can be minimized.

### Second Embodiment

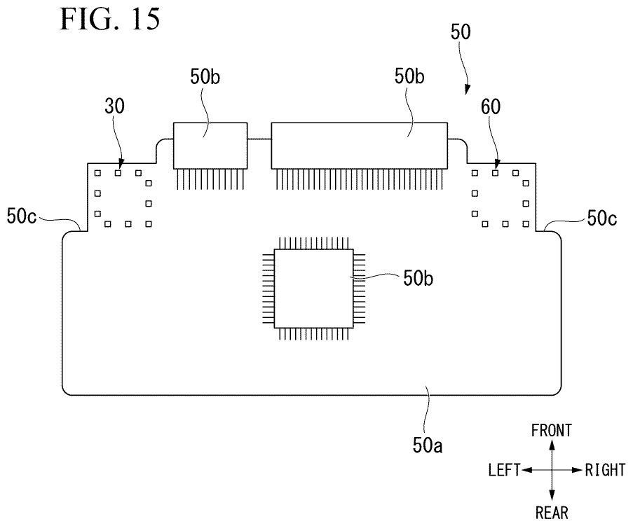

Next, a second embodiment of the present invention will be described with reference to FIGS. 14 and FIG. 15. In the description of the present embodiment, the description of the same parts as in the first embodiment will be omitted or simplified.

FIG. 14 is a schematic view of the electronic substrate 20 included in a voltage measurement device according to the present embodiment. As shown in the view, the electronic substrate 20 is provided with a second forward attachment portion 60 (third attachment portion), which is one of the attachment portions of the wireless module 21. The second forward attachment portion 60 is provided at a portion different from the forward attachment portion 30. Even in the voltage measurement device according to the present embodiment as above, since the plurality of attachment portions are provided, the wireless module 21 can be disposed by selecting a portion having a high radio wave intensity. As shown in FIG. 14, the notch portion 20c is provided also in the vicinity of the second forward attachment portion 60.

In the voltage measurement device according to the present embodiment as above, the installation position of the wireless module 21 can also be selected such that a null point is not generated in the specific use band at the position of the antenna portion 21b of the wireless module 21. Therefore, the voltage measurement device can reduce deterioration in communication quality due to interference of radio waves without providing a plurality of antennas.

FIG. 15 is a schematic view of the electronic substrate 50 included in the monitoring device according to the present embodiment.

As shown in the view, the electronic substrate 50 is also provided with the second forward attachment portion 60 (third attachment portion), which is one of the attachment portions of the wireless module. The second forward attachment portion 60 is provided at a portion different from the forward attachment portion 30. Even in the monitoring device according to the present embodiment as above, since the plurality of attachment portions are provided, the wireless module 21 can be disposed by selecting a portion having a high radio wave intensity. As shown in FIG. 15, the notch portion 50c is provided also in the vicinity of the second forward attachment portion 60.

In the monitoring device according to the present embodiment as above, the installation position of the wireless module can be selected such that a null point is not generated in the specific use band used by the wireless module at the position of the antenna portion of the wireless module. Therefore, the monitoring device can reduce degradation in communication quality due to interference of radio waves without providing a plurality of antennas.

In addition, a separation distance between the forward attachment portion 30 and the second forward attachment portion 60 is preferably ¼ to ½ of a wavelength of a radio wave used by the wireless module. That is, it is preferable that the forward attachment portion 30 and the second forward attachment portion 60 are disposed to be separated from each other by ¼ to ½ of the wavelength of the radio wave used by the wireless module. In this way, by disposing the forward attachment portion 30 and the second forward attachment portion 60 apart from each other, it is possible to reduce the generation of the null point by reducing reversal of phases of the radio waves emitted from the wireless module.

### Third Embodiment

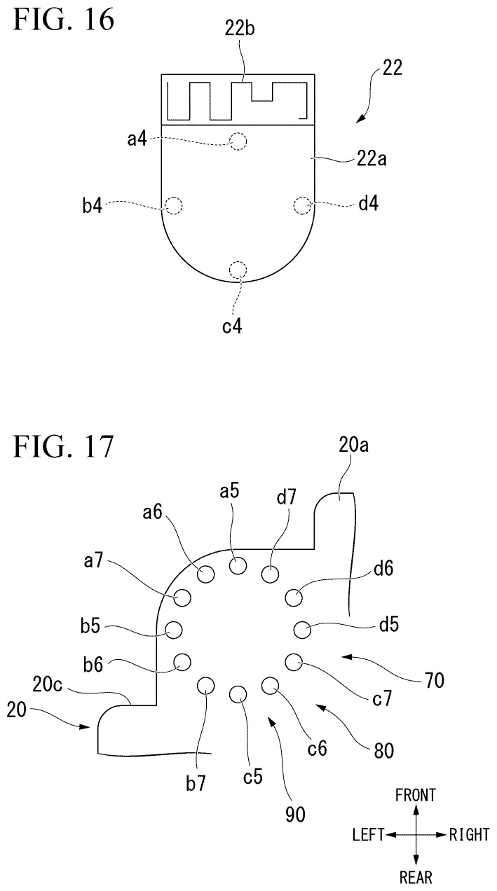

Next, a third embodiment of the present invention will be described with reference to FIG. 16 and FIG. 17. In the description of the present embodiment, the description of the same parts as in the first embodiment will be omitted or simplified.

FIG. 16 is a diagram schematically showing a front surface side of a wireless module 22 according to the present embodiment. The wireless module 22 includes a wireless IC chip 22a and an antenna portion 22b that protrudes sideways from the wireless IC chip 22a. In addition, the wireless module 22 includes a plurality of terminals a4 to d4 arranged along a circular shape.

FIG. 17 is an enlarged schematic view of part of the electronic substrate 20 according to the present embodiment. The electronic substrate 20 includes a forward attachment portion 70 (first attachment portion), a first inclined angle attachment portion 80 (second attachment portion), and a second inclined angle attachment portion 90 (third attachment portion). The forward attachment portion 70 includes a plurality of pads a5 to d5 arranged along a circular shape. In addition, the first inclined angle attachment portion 80 includes a plurality of pads a6 to d6 arranged in a concentric circular shape with the pads a5 to d5. In addition, the second inclined angle attachment portion 90 includes a plurality of pads a7 to d7 arranged in a concentric circular shape with the pads a5 to d5.

As described above, each of the forward attachment portion 70, the first inclined angle attachment portion 80, and the second inclined angle attachment portion 90 includes a plurality of pads to which the terminals a4 to d4 of the wireless module 22 are connected and which are arranged in the same pattern in the circular shape. The pads a6 to d6 of the first inclined angle attachment portion 80 are disposed at positions rotated by a set angle (30° in the present embodiment) to the left with respect to the pads a5 to d5 of the forward attachment portion 70. In addition, the pads a7 to d7 of the second inclined angle attachment portion 90 are disposed at positions rotated by a set angle (60° in the present embodiment) to the left with respect to the pads a5 to d5 of the forward attachment portion 70.

The pad a5, the pad a6, and the pad a7 are electrically connected to each other via a conductive portion (not shown). In addition, the pad b5, the pad b6, and the pad b7 are electrically connected to each other via a conductive portion (not shown). In addition, the pad c5, the pad c6, and the pad c7 are electrically connected to each other via a conductive portion (not shown). That is, each of the pads a6 to d6 of the first inclined angle attachment portion 80 and the pads a7 to d7 of the second inclined angle attachment portion 90 is electrically connected to the pads a5 to d5 of the second forward attachment portion 60 at a position rotated by a set angle with a center position as a center.

With the voltage measurement device according to the present embodiment as above, the wireless module 22 can be disposed in a direction between the forward direction and the leftward direction. Further, the electronic substrate 20 includes a plurality of inclined angle attachment portions (the first inclined angle attachment portion 80 and the second inclined angle attachment portion 90) having different set angles. Therefore, the wireless module 22 can be disposed in a plurality of directions between the forward direction and the leftward direction.

The notch portion 20c is formed in an arc shape such that part of the electronic substrate 20 does not face the antenna portion 22b even in a case where the wireless module 22 is attached to any one of the forward attachment portion 70, the first inclined angle attachment portion 80, or the second inclined angle attachment portion 90.

In the present embodiment, the configuration in which the forward attachment portion 70, the first inclined angle attachment portion 80, and the second inclined angle attachment portion 90 are provided on the electronic substrate 20 has been described, but the forward attachment portion 70, the first inclined angle attachment portion 80, and the second inclined angle attachment portion 90 may be provided in the monitoring device.

Although the preferred embodiments of the present invention have been described above with reference to the accompanying drawings, it goes without saying that the present invention is not limited to the above embodiments. The various shapes, combinations, and the like of each constituent members shown in the above-described embodiment are merely examples and can be variously changed based on design requirements and the like without departing from the gist of the present invention.

For example, in the present invention, the number of attachment portions is not limited to two. For example, three or more attachment portions may be provided.

In addition, in the above-described embodiment, a configuration in which each of the voltage measurement device and the monitoring device is the electronic substrate unit according to the present invention has been described. However, it is also possible to adopt a configuration in which any one of the voltage measurement device or the monitoring device is the electronic substrate unit according to the present invention.

The embodiments described above can also be described as, for example, the following appendices.

### Appendix 1

An electronic substrate unit that is accommodated inside a housing of a battery pack, the electronic substrate unit including
an electronic substrate on which a circuit is formed, and
a wireless module mounted on the electronic substrate,
in which the electronic substrate includes a plurality of attachment portions of the wireless module, and
the wireless module is provided on the electronic substrate in a one-on-one manner and is attached to one of the plurality of attachment portions.

### Appendix 2

The electronic substrate unit according to Appendix 1,
in which the electronic substrate includes
a first attachment portion that is one of the attachment portions, and
a second attachment portion that is the attachment portion in which an orientation of the wireless module viewed in a normal direction of the electronic substrate in a case where the wireless module is attached is different from an orientation of the first attachment portion, and
the first attachment portion and the second attachment portion are disposed on the electronic substrate to overlap each other when viewed in the normal direction.

### Appendix 3

The electronic substrate unit according to Appendix 2,
in which each of the first attachment portion and the second attachment portion includes a plurality of terminal connection portions to which a terminal of the wireless module is connected, and which are arranged in the same pattern in a rectangular shape,
the terminal connection portions of the second attachment portion are provided at positions rotated by 90° with respect to the terminal connection portions of the first attachment portion with a center position of the rectangular shape as a center, and
each of the terminal connection portions of the second attachment portion is electrically connected to the terminal connection portion of the first attachment portion at the position rotated by 90° with the center position as the center.

### Appendix 4

The electronic substrate unit according to Appendix 2,
in which each of the first attachment portion and the second attachment portion includes a plurality of terminal connection portions to which a terminal of the wireless module is connected, and which are arranged in the same pattern in a circular shape,
the terminal connection portions of the second attachment portion are provided at positions rotated by a set angle with respect to the terminal connection portions of the first attachment portion with a center position of the circular shape as a center, and
each of the terminal connection portions of the second attachment portion is electrically connected to respective one of the terminal connection portions of the first attachment portion at the position rotated by the set angle with the center position as the center.

### Appendix 5

The electronic substrate unit according to Appendix 4,
in which the electronic substrate includes a plurality of the second attachment portions having different set angles.

### Appendix 6

The electronic substrate unit according to Appendix 1,
in which the electronic substrate includes
a first attachment portion that is one of the attachment portions, and
a third attachment portion that is the attachment portion different from the first attachment portion, and
the first attachment portion and the third attachment portion are provided at different portions of the electronic substrate.

### Appendix 7

The electronic substrate unit according to Appendix 6,
in which the first attachment portion and the third attachment portion are disposed to be separated from each other by ¼ to ½ of a wavelength of a radio wave used by the wireless module.

### Appendix 8

The electronic substrate unit according to any one of Appendices 1 to 7,
in which the wireless module includes a wireless IC chip including a terminal connected to the electronic substrate, and an antenna portion provided to protrude sideways from the wireless IC chip.

### Appendix 9

The electronic substrate unit according to Appendix 8,
in which the electronic substrate includes a notch portion provided at a position with a possibility of facing the antenna portion.

### Appendix 10

The electronic substrate unit according to any one of Appendices 1 to 9,
in which a voltage detection circuit configured to measure a voltage of a battery module is formed as the circuit in the electronic substrate.

### Appendix 11

A battery monitoring system including
a plurality of battery modules,
a voltage measurement device provided in each of the battery modules, and
a monitoring device configured to perform wireless communication with the voltage measurement device,
in which at least one of the voltage measurement devices and the monitoring device includes the electronic substrate unit according to any one of Appendices 1 to 10.

### Appendix 12

The battery monitoring system according to Appendix 11,
in which both the voltage measurement device and the monitoring device include the electronic substrate unit according to any one of Appendices 1 to 10, and
each of the voltage measurement device and the monitoring device includes the wireless modules in a one-on-one manner.

### REFERENCE SIGNS LIST

20 Electronic substrate
20a Printed substrate
20b Electronic component
20c Notch portion
21 Wireless module
21a Wireless IC chip
21b Antenna portion
22 Wireless module
22a Wireless IC chip
22b Antenna portion
30 Forward attachment portion (first attachment portion)
40 Leftward attachment portion (second attachment portion)
50 Electronic substrate
50a Printed substrate
50b Electronic component
50c Notch portion
60 Second forward attachment portion (third attachment portion)
70 Forward attachment portion (first attachment portion)
80 First inclined angle attachment portion (second attachment portion)
90 Second inclined angle attachment portion (second attachment portion)
A Voltage measurement device (electronic substrate unit)
a1 to j1 Terminal
a2 to j2 Pad (terminal connection portion)
a3 to j3 Pad (terminal connection portion)
a4 to d4 Terminal
a5 to d5 Pad (terminal connection portion)
a6 to d6 Pad (terminal connection portion)
a7 to d7 Pad (terminal connection portion)
B Monitoring device (electronic substrate unit)
C Housing
H Through-hole
L1 First conductor layer
L2 Second conductor layer
L3 Third conductor layer
L4 Fourth conductor layer
Lb Connection line
Lc Connection line
Ld Connection line
Le Connection line
Lf Connection line
Lg Connection line
Lh Connection line
Li Connection line
Lj Connection line
M Battery module
P Battery pack
S Battery monitoring system

1. An electronic substrate unit that is accommodated inside a housing of a battery pack, the electronic substrate unit comprising:
an electronic substrate on which a circuit is formed; and
a wireless module mounted on the electronic substrate,
wherein the electronic substrate includes a plurality of attachment portions of the wireless module, and
the wireless module is provided on the electronic substrate in a one-on-one manner and is attached to one of the plurality of attachment portions.

2. The electronic substrate unit according to claim 1,
wherein the electronic substrate includes
a first attachment portion that is one of the attachment portions, and
a second attachment portion that is the attachment portion in which an orientation of the wireless module viewed in a normal direction of the electronic substrate in a case where the wireless module is attached is different from an orientation of the first attachment portion, and
wherein the first attachment portion and the second attachment portion are disposed on the electronic substrate to overlap each other when viewed in the normal direction.

3. The electronic substrate unit according to claim 2,
wherein each of the first attachment portion and the second attachment portion includes a plurality of terminal connection portions to which a terminal of the wireless module is connected, and which are arranged in the same pattern in a rectangular shape,
the terminal connection portions of the second attachment portion are provided at positions rotated by 90° with respect to the terminal connection portions of the first attachment portion with a center position of the rectangular shape as a center, and
each of the terminal connection portions of the second attachment portion is electrically connected to respective one of the terminal connection portions of the first attachment portion at the position rotated by 90° with the center position as the center.

4. The electronic substrate unit according to claim 2,
wherein each of the first attachment portion and the second attachment portion includes a plurality of terminal connection portions to which a terminal of the wireless module is connected, and which are arranged in the same pattern in a circular shape,
the terminal connection portions of the second attachment portion are provided at positions rotated by a set angle with respect to the terminal connection portions of the first attachment portion with a center position of the circular shape as a center, and
each of the terminal connection portions of the second attachment portion is electrically connected to respective one of the terminal connection portions of the first attachment portion at the position rotated by the set angle with the center position as the center.

5. The electronic substrate unit according to claim 4,
wherein the electronic substrate includes a plurality of the second attachment portions having different set angles.

6. The electronic substrate unit according to claim 1,
wherein the electronic substrate includes
a first attachment portion that is one of the attachment portions, and
a third attachment portion that is the attachment portion different from the first attachment portion, and
the first attachment portion and the third attachment portion are provided at different portions of the electronic substrate.

7. The electronic substrate unit according to claim 6,
wherein the first attachment portion and the third attachment portion are disposed to be separated from each other by ¼ to ½ of a wavelength of a radio wave used by the wireless module.

8. The electronic substrate unit according to claim 1,
wherein the wireless module includes a wireless IC chip including a terminal connected to the electronic substrate, and an antenna portion provided to protrude sideways from the wireless IC chip.

9. The electronic substrate unit according to claim 8,
wherein the electronic substrate includes a notch portion provided at a position with a possibility of facing the antenna portion

10. The electronic substrate unit according to claim 1,
wherein a voltage detection circuit configured to measure a voltage of a battery module is formed as the circuit in the electronic substrate.

11. A battery monitoring system comprising:
a plurality of battery modules;
a voltage measurement device provided in each of the battery modules; and
a monitoring device configured to perform wireless communication with the voltage measurement device,
wherein at least one of the voltage measurement devices and the monitoring device includes the electronic substrate unit according to claim 1.

12. A battery monitoring system comprising:
a plurality of battery modules;
a voltage measurement device provided in each of the battery modules; and
a monitoring device configured to perform wireless communication with the voltage measurement device,
wherein both the voltage measurement device and the monitoring device include the electronic substrate unit according to claim 1, and
each of the voltage measurement device and the monitoring device includes the wireless modules in a one-on-one manner.
